(19) United States
(12) Patent Application Publication
(10) Pub. No.: US 2026/0225939 A1
(43) Pub. Date: Aug. 6, 2026

(54) GLASS

(71) Applicant: AGC Inc., Tokyo (JP)

(72) Inventors: Rikiya KADO, Tokyo (JP); Hirofumi TOKUNAGA, Tokyo (JP); Mamoru ISOBE, Tokyo (JP); Yuha KOBAYASHI, Tokyo (JP)

(73) Assignee: AGC Inc., Tokyo (JP)

(21) Appl. No.: 19/630,460

(22) Filed: Mar. 27, 2026

Related U.S. Application Data
(63) Continuation of application No. PCT/JP2024/036288, filed on Oct. 10, 2024.

(30) Foreign Application Priority Data
Oct. 13, 2023 (JP) 2023-177362

(51) Int. Cl. C03C 3/087; C03C 3/093; C03C 3/095; H10P 72/70

(52) U.S. Cl. CPC C03C 3/087; C03C 3/093; C03C 3/095; C03C 2201/10; C03C 2201/32; C03C 2201/3411; C03C 2201/36; C03C 2201/40; C03C 2201/54; H10P 72/7424; H10P 72/7436

(57) ABSTRACT

Fracture is prevented while reducing the coefficient of thermal expansion and production is facilitated. The glass 10 has a parameter A of 0.1 or more and 1.0 or less, a parameter B of 1.75 or more and 2.10 or less, and a Young's modulus of 110 GPa or more.

### CROSS-REFERENCE TO RELATED APPLICATION(S)

This application is a continuation of International Application No. PCT/JP2024/036288, filed on Oct. 10, 2024 which claims the benefit of priority of the prior Japanese Patent Application No. 2023-177362, filed on Oct. 13, 2023, the entire contents of which are incorporated herein by reference.

### BACKGROUND OF THE INVENTION

### 1. Field of the Invention

The present invention relates to glass.

### 2. Description of the Related Art

Glass may be used as a member for supporting a semiconductor device during the production process of the semiconductor device. For example, JP 2021-20840 A describes a supporting glass substrate having a high Young's modulus in order to prevent deflection. In addition, the coefficient of thermal expansion may be lowered in order to prevent deflection due to the temperature change.

When the Young's modulus of the glass is increased in order to prevent the deflection as described above, a structure having a high ion filling rate is generally obtained. There is a strong tendency that glass with a high ion filling rate has a high coefficient of thermal expansion, and it is not easy to achieve both increasing the Young's modulus and decreasing the coefficient of thermal expansion. In addition, the glass with a high ion filling rate tends to have an increased specific elastic modulus E/ρ (Young's modulus/density), and may easily crack during processing. In addition, for example, when the glass has a too small specific elastic modulus E/ρ, the glass is easy to fracture and becomes too heavy, so that it may be difficult to handle in the process, and the control of the specific elastic modulus is related to ease of production.

### SUMMARY OF THE INVENTION

It is an object of the present invention to at least partially solve the problems in the conventional technology.

A glass of the present disclosure has a parameter A represented by Formula (1) of 0.1 or more and 1.0 or less, a parameter B represented by Formula (2) of 1.75 or more and 2.10 or less, and a Young's modulus of 110 GPa or more.

$$A = [ R O ] / [ {RE}_{2} {O}_{3} ] \qquad ( 1 )$$

$$B = {\{ ( 441 - 2.845 \times [ {SiO}_{2} ] - 1.833 \times [ {Al}_{2} {O}_{3} ] - 3.864 \times [ {B}_{2} {O}_{3} ] - 1.569 \times [ MgO ] - 2.252 \times [ CaO ] - 4.031 \times [ SrO ] - 3.384 \times [ BaO ] - 0.956 \times [ {Li}_{2} O ] - 2. \times [ ZnO ] - 0.554 \times [ {ZrO}_{2} ] - 2.815 \times [ {TiO}_{2} ] + 1.636 \times [ {Y}_{2} {O}_{3} ] - 0.651 \times [ {Gd}_{2} {O}_{3} ] - 0.911 \times [ {La}_{2} {O}_{3} ] ) / ( 29.637 - 0.1851 \times [ {SiO}_{2} ] - 0.1408 \times [ {Al}_{2} {O}_{3} ] - 0.1984 \times [ {B}_{2} {O}_{3} ] - 0.1343 \times [ MgO ] - 0.1271 \times [ CaO ] - 0.0556 \times [ SrO ] + 0.0369 \times [ BaO ] - 0.1083 \times [ {Li}_{2} O ] - 0.0134 \times [ ZnO ] + 0.0192 \times [ {ZrO}_{2} ] - 0.1408 \times [ {TiO}_{2} ] + 0.0794 \times [ {Y}_{2} {O}_{3} ] + 0.3092 \times [ {Gd}_{2} {O}_{3} ] + 0.1983 \times [ {La}_{2} {O}_{3} ] ) - 10 \}}^{0.5} \qquad ( 2 )$$

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a schematic view of the glass according to the present embodiment; and

FIG. 2 is a schematic view for explaining deflection evaluation.

### DETAILED DESCRIPTION OF THE PREFERRED EMBODIMENTS

Hereinafter, preferred embodiments of the present invention will be described in detail with reference to the accompanying drawings. The present invention is not limited by the embodiments, and in a case where there are a plurality of embodiments, the present invention includes a combination of the embodiments. The numerical value includes a range of rounding. In addition, a numerical range represented by “to” means a numerical range including numerical values before and after “to” as a lower limit value and an upper limit value, and when “to” is used in the following description, the same meaning is given. The upper limit value and the lower limit value indicated in the numerical range can be appropriately combined.

### Glass

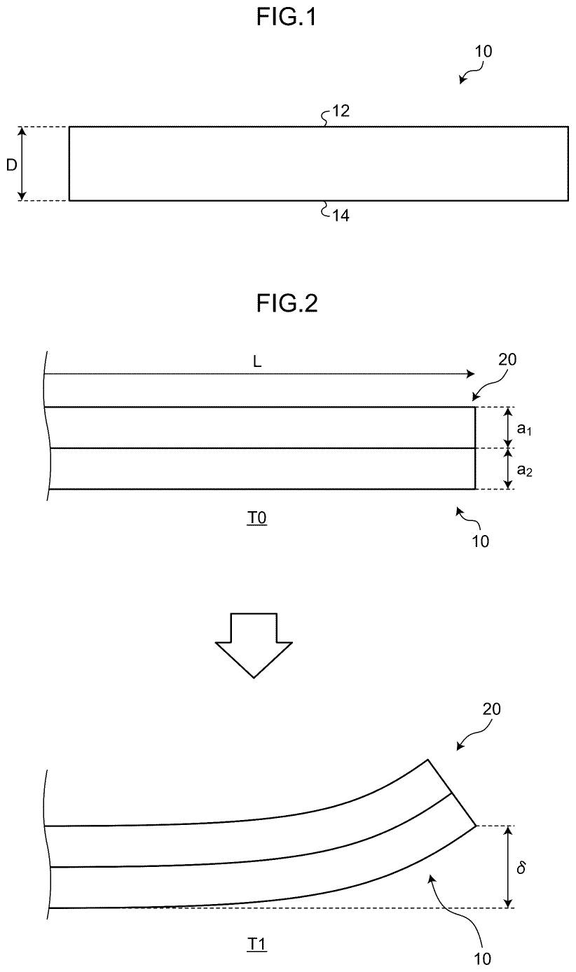

FIG. 1 is a schematic view of the glass according to the present embodiment. As illustrated in FIG. 1, the glass 10 according to the present embodiment is used as a glass substrate for producing a semiconductor package, and more specifically, is a supporting glass substrate for producing FOWLP and the like. However, the application of the glass 10 is not limited to the production of FOWLP and the like and may be any application, and the glass 10 may be a glass substrate used for supporting a member or may be used for an application other than the support of a member. Note that FOWLP and the like include a fan out wafer level package (FOWLP) and a fan out panel level package (FOPLP).

### Composition of Glass

Next, a preferred composition of the glass 10 will be described.

### Parameter A

The parameter A of the glass 10 is expressed by the following Formula (1).

$$A = [ R O ] / [ {RE}_{2} {O}_{3} ] \qquad ( 1 )$$

The content of the oxide AₓO_{y} (wherein A is an element constituting an oxide, and x and y are any integers) contained in the glass 10 in terms of oxide-based molo is represented by [AₓO_{y}]. The content here refers to the ratio of the content of the oxide AₓO_{y} to the entire glass 10 in terms of oxide-based mol %. RE refers to a divalent metal, and RO refers to an oxide of a divalent metal R. RE refers to a trivalent rare earth metal, and RE₂O₃ refers to an oxide of trivalent rare earth metal RE. For example, RE is at least one of Y, Gd, La, Ga, and Nd.

That is, for example, [RO] in Formula (1) refers to the ratio of the content of RO to the entire glass 10 in terms of oxide-based mol %, and [RE₂O₃] refers to the ratio of the content of RE₂O₃ to the entire glass 10 in terms of oxide-based mol %.

The content of RO refers to the total content of divalent oxides. The total content of the divalent oxide refers to the total content of the divalent oxide when a plurality of kinds of divalent oxides are contained, and refers to the content of the divalent oxide when one kind of divalent oxide is contained. Similarly, the content of RE₂O₃ refers to the total content of trivalent rare earth metal oxides, refers to the total content of the trivalent rare earth metal oxides when a plurality of kinds of trivalent rare earth metal oxides are contained, and refers to the content of the trivalent rare earth metal oxide when one kind of trivalent rare earth metal oxide is contained.

The glass 10 preferably has a parameter A of 0.1 or more and 1.1 or less, more preferably 0.3 or more and 1.05 or less, and still more preferably 0.5 or more and 1.00 or less. The parameter A within this range can lead to a decrease in the coefficient of thermal expansion while increasing the Young's modulus.

### Parameter B

The parameter B of the glass 10 is expressed by the following Formula (2).

$$B = {\{ ( 441 - 2.845 \times [ {SiO}_{2} ] - 1.833 \times [ {Al}_{2} {O}_{3} ] - 3.864 \times [ {B}_{2} {O}_{3} ] - 1.569 \times [ MgO ] - 2.252 \times [ CaO ] - 4.031 \times [ SrO ] - 3.384 \times [ BaO ] - 0.956 \times [ {Li}_{2} O ] - 2. \times [ ZnO ] - 0.554 \times [ {ZrO}_{2} ] - 2.815 \times [ {TiO}_{2} ] + 1.636 \times [ {Y}_{2} {O}_{3} ] - 0.651 \times [ {Gd}_{2} {O}_{3} ] - 0.911 \times [ {La}_{2} {O}_{3} ] ) / ( 29.637 - 0.1851 \times [ {SiO}_{2} ] - 0.1408 \times [ {Al}_{2} {O}_{3} ] - 0.1984 \times [ {B}_{2} {O}_{3} ] - 0.1343 \times [ MgO ] - 0.1271 \times [ CaO ] - 0.0556 \times [ SrO ] + 0.0369 \times [ BaO ] - 0.1083 \times [ {Li}_{2} O ] - 0.0134 \times [ ZnO ] + 0.0192 \times [ {ZrO}_{2} ] - 0.1408 \times [ {TiO}_{2} ] + 0.0794 \times [ {Y}_{2} {O}_{3} ] + 0.3092 \times [ {Gd}_{2} {O}_{3} ] + 0.1983 \times [ {La}_{2} {O}_{3} ] ) - 10 \}}^{0.5} \qquad ( 2 )$$

The glass 10 may not contain all the oxides represented by Formula (2). In Formula (2), the content of the oxide not contained in the glass 10 is treated as 0. The glass 10 may contain a component other than the oxides represented by Formula (2).

The glass 10 preferably has a parameter B of 1.75 or more and 2.10 or less, more preferably 1.78 or more and 2.05 or less, more preferably 1.85 or more and 2.0 or less, and still more preferably 1.9 or more and 1.95 or less. The parameter B within this range can set the ratio of the Young's modulus E to the density ρ (E/φ) of the glass 10 within an appropriate range, and can facilitate the production while preventing the fracture.

### SiO₂

SiO₂ is a component for decreasing the linear thermal expansion coefficient and is a component for controlling the Young's modulus. Therefore, the glass 10 preferably contains SiO₂ (the content of SiO₂ is higher than 0 mol %). In order to increase E/ρ, the content of SiO₂ is preferably 60% or less in terms of oxide-based mol %. The glass 10 preferably has a content of SiO₂ of 45.0% or more and 60.0% or less, more preferably 48% or more and 58% or less, more preferably 51% or more and 56% or less, and still more preferably 52% or more and 55% or less. The content of SiO₂ within this range can prevent the fracture while reducing the coefficient of thermal expansion, and can facilitate the production.

Al₂O₃

Al₂O₃ has an effect of increasing Young's modulus to prevent the deflection, and preventing phase separation of glass. Therefore, the glass 10 preferably contains Al₂O₃. The glass 10 preferably has a content of Al₂O₃ of 10.0% or more and 26.0% or less, more preferably 12.0% or more and 23.0% or less, more preferably 13.0% or more and 22.0% or less, more preferably 14.0% or more and 21.0% or less, more preferably 15.0% or more and 20.0% or less, and still more preferably 16.0% or more and 19.0% or less in terms of oxide-based mol %. The content of Al₂O₃ within this range can prevent the fracture while reducing the coefficient of thermal expansion, and can facilitate the production.

B₂O₃

B₂O₃ has an effect of decreasing the density and the Young's modulus. Therefore, the glass 10 may not contain B₂O₃ (the content of B₂O₃ is 0 mol %), but may contain B₂O₃. The glass 10 preferably has a content of B₂O₃ of 0.1% or more and 10.0% or less, more preferably 0.3% or more and 9.0% or less, more preferably 0.5% or more and 8.0% or less, more preferably 0.8% or more and 7.0% or less, more preferably 1.08 or more and 6.0% or less, more preferably 1.5% or more and 5.0% or less, more preferably 1.8% or more and 4% or less, and still more preferably 2.0% or more and 3.0% or less in terms of oxide-based mol %. The content of B₂O₃ within this range can prevent the fracture while reducing the coefficient of thermal expansion, and can facilitate the production.

### RO

The glass 10 preferably has a total content of the divalent oxide RO of more than 0% and 20.0% or less, more preferably 2.0% or more and 18.0% or less, more preferably 4.0% or more and 16.0% or less, more preferably 6.0% or more and 14.0% or less, more preferably 8.0% or more and 12.0% or less, and still more preferably 9.0% or more and 11.0% or less in terms of oxide-based mol %. The total content of RO within this range can reduce the coefficient of thermal expansion.

### MgO

MgO can prevent the deflection by increasing the ratio (E/ρ) since MgO increases the Young's modulus without increasing the density, and. MgO also has an effect of reducing the linear thermal expansion coefficient. Therefore, the glass 10 may not contain MgO, but may contain MgO. Meanwhile, by setting the content of MgO to 20% or less in terms of oxide-based mol %, it is possible to prevent the ratio (E/ρ) from becoming too high. The glass 10 preferably has a content of MgO of 0.1% or more and 20.0% or less, more preferably 1.0% or more and 18.0% or less, more preferably 2.0% or more and 16.0% or less, more preferably 3.0% or more and 14.0% or less, more preferably 3.5% or more and 12.0% or less, more preferably 4.0% or more and 10.0% or less, and still more preferably 4.5% or more and 8.0% or less. The content of MgO within this range can prevent the fracture while reducing the coefficient of thermal expansion, and can facilitate the production.

### CaO

An oxide of the group 2 element has an effect of increasing the ratio (E/ρ) second to MgO. Therefore, the glass 10 may not contain Cao, but may contain Cao. The glass 10 preferably has a content of Cao of 0.1% or more and 20.0% or less, more preferably 1.08 or more and 15.0% or less, more preferably 2.0% or more and 12.0% or less, more preferably 3.0% or more and 10.0% or less, more preferably 3.5% or more and 8.0% or less, and still more preferably 4.0% or more and 6.0% or less in terms of oxide-based mol %. The content of CaO within this range can prevent the fracture while reducing the coefficient of thermal expansion, and can facilitate the production.

### SrO

SrO has an effect of increasing the density and controlling the Young's modulus. Therefore, the glass 10 may not contain SrO, but may contain SrO. An increase in the linear thermal expansion coefficient can be prevented by setting the content of SrO to 20.0% or less in terms of oxide-based mol %. The glass 10 preferably has a content of SrO of 0.1% or more and 20.0% or less, more preferably 0.5% or more and 15.0% or less, more preferably 1.0% or more and 10.0% or less, and still more preferably 2.08 or more and 7.0% or less. The content of SrO within this range can prevent the fracture while reducing the coefficient of thermal expansion, and can facilitate the production.

### BaO

Bao has a greater effect of increasing the density than SrO, and the glass 10 may not contain Bao but may contain Bao. The glass 10 preferably has a content of BaO of 0.1% or more and 20.0% or less, more preferably 1.0% or more and 15.0% or less, more preferably 2.08 or more and 12.0% or less, more preferably 3.0% or more and 10.0% or less, more preferably 3.5% or more and 8.0% or less, and still more preferably 4.0% or more and 6.0% or less in terms of oxide-based mol %. The content of BaO within this range can prevent the fracture while reducing the coefficient of thermal expansion, and can facilitate the production.

### ZnO

ZnO has an effect of increasing the Young's modulus. Therefore, the glass 10 may not contain ZnO, but may contain ZnO. An increase in the linear thermal expansion coefficient can be prevented by setting the content of ZnO to 10.0% or less in terms of oxide-based mol %. The glass 10 preferably has a content of ZnO of 0.1% or more and 10.0% or less, more preferably 1.0% or more and 8.0% or less, more preferably 1.5% or more and 7.0% or less, and still more preferably 2.0% or more and 6.0% or less. The content of ZnO within this range can prevent the fracture while reducing the coefficient of thermal expansion, and can facilitate the production.

### Alkali Metal Oxide

The glass 10 is preferably alkali-free glass. The alkali-free glass does not substantially contain an alkali metal oxide such as Li₂O, Na₂O, or K₂O. Here, the phrase “does not substantially contain an alkali metal oxide” means that an alkali metal oxide other than inevitable impurities mixed from raw materials and the like is not contained. That is, it means that an alkali metal oxide is not intentionally contained.

For example, the glass 10 preferably has a content of Li₂O of 0%, a content of Na₂O of 0%, and a content of K₂O of 0% in terms of oxide-based mol %.

### ZrO₂

ZrO₂ can increase the Young's modulus without relatively decreasing the linear thermal expansion coefficient. Therefore, the glass 10 may not contain ZrO₂, but may contain ZrO₂. Manufacturability can be controlled by setting the content of ZrO₂ to 5.0% or less in terms of oxide-based mol %. The glass 10 preferably has a content of ZrO₂ of 0.1% or more and 5.0% or less, more preferably 0.3% or more and 4.0% or less, more preferably 0.5% or more and 3.5% or less, more preferably 0.6% or more and 3.0% or less, more preferably 0.7% or more and 2.5% or less, more preferably 0.8% or more and 2.0% or less, more preferably 0.9% or more and 1.5% or less, and still more preferably 1.0% or more and 1.4% or less. The content of ZrO₂ within this range can prevent the fracture while reducing the coefficient of thermal expansion, and can facilitate the production.

### TiO₂

TiO₂ can increase the Young's modulus without relatively decreasing the linear thermal expansion coefficient. Therefore, the glass 10 may not contain TiO₂, but may contain TiO₂. The manufacturability can be controlled by setting the content of TiO₂ to 10.0% or less in terms of oxide-based mol %. The glass 10 preferably has a content of TiO₂ of 0.1% or more and 10.0% or less, more preferably 0.3% or more and 9.0% or less, more preferably 0.5% or more and 8.0% or less, more preferably 0.8% or more and 7.0% or less, more preferably 1.0% or more and 6.0% or less, and still more preferably 1.5% or more and 5.0% or less in terms of oxide-based mol %. The content of TiO₂ within this range can prevent the fracture while reducing the coefficient of thermal expansion, and can facilitate the production.

RE₂O₃

The trivalent oxide RE₂O₃ has an effect of increasing the Young's modulus of the glass. Therefore, the glass 10 may not contain RE₂O₃, but preferably contains RE₂O₃. When the content of RE₂O₃ exceeds 20.0% in terms of oxide-based mol %, the density becomes too high, and thus the glass 10 preferably has a total content of RE₂O₃ of 0.1% or more and 20.0% or less, more preferably 3.0% or more and 18.0% or less, more preferably 5.0% or more and 16.0% or less, more preferably 7.0% or more and 15.0% or less, more preferably 8.0% or more and 14.0% or less, more preferably 9.0% or more and 13.0% or less, and still more preferably 10.0% or more and 12.0% or less. In addition, the glass 10 preferably has a total content of RE₂O₃ of 10.0% or more and 20.0% or less. The total content of RE₂O₃ within this range can prevent the fracture while reducing the coefficient of thermal expansion, and can facilitate the production.

Y₂O₃

The glass 10 may not contain Y₂O₃, but may contain Y₂O₃. The glass 10 preferably has a content of Y₂O₃ of 0.1% or more and 20.0% or less, more preferably 3.0% or more and 18.0% or less, more preferably 5.0% or more and 16.0% or less, more preferably 6.0% or more and 14.0% or less, more preferably 7.0% or more and 12.0% or less, and still more preferably 8.0% or more and 10.0% or less in terms of oxide-based mol %. The content of Y₂O₃ within this range can prevent the fracture while reducing the coefficient of thermal expansion, and can facilitate the production.

Gd₂O₃

The glass 10 may not contain Gd₂O₃, but may contain Gd₂O₃. The glass 10 preferably has a content of Gd₂O₃ of 0.1% or more and 10.0% or less, more preferably 0.5% or more and 7.0% or less, more preferably 1.0% or more and 5.0% or less, more preferably 1.5% or more and 4.0% or less, and still more preferably 2.0% or more and 3.5% or less in terms of oxide-based mol %. The content of Gd₂O₃ within this range can prevent the fracture while reducing the coefficient of thermal expansion, and can facilitate the production.

La₂O₃

The glass 10 may not contain La₂O₃, but may contain La₂O₃. The glass 10 preferably has a content of La₂O₃ of 0.1% or more and 10.0% or less, more preferably 0.5% or more and 7.0% or less, more preferably 1.0% or more and 5.0% or less, more preferably 1.5% or more and 4.0% or less, and still more preferably 2.0% or more and 3.5% or less in terms of oxide-based mol %. The content of La₂O₃ within this range can prevent the fracture while reducing the coefficient of thermal expansion, and can facilitate the production.

P₂O₅

The glass 10 may not contain P₂O₅, but may contain P₂O₅. The glass 10 preferably has a content of P₂O₅ of 0.1% or more and 5.0% or less, more preferably 0.3% or more and 3.0% or less, and still more preferably 0.5% or more and 1.5% or less in terms of oxide-based mol %. The content of P₂O₅ within this range can prevent the fracture while reducing the coefficient of thermal expansion, and can facilitate the production.

V₂O₅

The glass 10 may not contain V₂O₅, but may contain V₂O₅. The glass 10 preferably has a content of V₂O₅ of 0.01% or more and 1.0% or less, and still more preferably 0.1% or more and 0.5% or less in terms of oxide-based mol %. The content of V₂O₅ within this range can prevent the fracture while reducing the coefficient of thermal expansion, and can facilitate the production.

### PbO

The glass 10 preferably does not contain PbO. The glass 10 preferably has a content of PbO of 0.1% or less, more preferably 0.05% or less, and still more preferably 0.01% or less in terms of oxide-based mol %. The content of PbO within this range can reduce environmental load.

Fe₂O₃

The glass 10 preferably does not contain Fe₂O₃. The glass 10 preferably has a content of Fe₂O₃ in terms of external ratio of 0.1% or less, more preferably 0.001% or more and 0.05% or less, and still more preferably 0.005% or more and 0.01% or less in terms of oxide-based mass %. The content of Fe₂O₃ as low as described above can prevent a decrease in light transmittance.

Note that the content of Fe₂O₃ in terms of external ratio refers to the ratio of the mass of Fe₂O₃ contained in the glass 10 to the total value of the mass of all the components of the glass 10 excluding Fe₂O₃ on an oxide basis.

The glass 10 preferably has a ratio of the content of RO to the total content of SiO₂, Al₂O₃, and B₂O₃ ((RO)/(SiO₂+Al₂O₃+B₂O₃)) of 0.00 or more and 0.50 or less, more preferably 0.03 or more and 0.40 or less, more preferably 0.05 or more and 0.30 or less, more preferably 0.07 or more and 0.25 or less, more preferably 0.08 or more and 0.20 or less, more preferably 0.10 or more and 0.18 or less, more preferably 0.11 or more and 0.17 or less, more preferably 0.12 or more and 0.16 or less, and still more preferably 0.13 or more and 0.15 or less in terms of oxide-based mol %. The ratio ((RO)/(SiO₂+Al₂O₃+B₂O₃)) within this range can achieve both the Young's modulus and moldability.

The glass 10 preferably has a ratio of the content of MgO to the content of RO ((MgO)/(RO)) of 0.10 or more and 0.90 or less, more preferably 0.20 or more and 0.80 or less, more preferably 0.30 or more and 0.70 or less, and still more preferably 0.40 or more and 0.60 or less in terms of oxide-based mol %. The ratio ((MgO)/(RO)) within this range can increase the Young's modulus while preventing an increase in the density.

The glass 10 preferably has a ratio of the total content of ZrO₂+TiO₂ to the content of RE₂O₃ in terms of oxide-based mol % ((ZrO₂+TiO₂)/(RE₂O₃)) of 0.05 or more and 0.90 or less, more preferably 0.10 or more and 0.70 or less, and still more preferably 0.20 or more and 0.50 or less in terms of oxide-based mol %. The ratio ((ZrO₂+TiO₂)/(RE₂O₃)) within this range can control the ratio (E/ρ) so as not to be excessively high while increasing the Young's modulus.

The glass 10 preferably does not contain a sintered body. That is, the glass 10 is preferably glass that is not a sintered body. Here, the sintered body refers to a member in which a plurality of particles are heated at a temperature lower than the melting point to bond the particles. The sintered body has a relatively high porosity because the sintered body includes holes, but the glass 10 has a low porosity that is usually 0% because the glass is not a sintered body. However, it is allowable to include an inevitable trace amount of pores. The porosity here is a so-called true porosity, and refers to a value obtained by dividing a sum of volumes of pores (holes) communicating with the outside and pores (holes) not communicating with the outside by a total volume (apparent volume). The porosity can be measured according to, for example, JIS R 1634:1998 “Test methods for density and apparent porosity of fine ceramics”.

Preferably, the glass contained in the glass 10 is usually amorphous glass, that is, amorphous solid. This glass may be crystallized glass containing crystals on the surface or inside, but is preferably amorphous glass from the viewpoint of density. Among the ceramics, those prepared by a sintering method are preferably not used because they have a low transmittance and a high density.

### Shape of Glass

Next, the shape of the glass 10 will be described. As illustrated in FIG. 1, the glass 10 is a plate-like glass substrate including a surface 12 which is a principal surface on one side and a surface 14 which is a principal surface opposite to the surface 12. The surface 14 may be, for example, parallel to the surface 12. The glass 10 may have a circular disk shape in plan view, that is, when viewed from a direction orthogonal to the surface 12, but is not limited to the disk shape and may have any shape, and for example, may be a polygonal plate such as a rectangle. Note that the shape also includes a shape in which a recess such as a notch or an orientation flat is provided on the outer periphery.

The glass 10 preferably has a thickness D, which is the length between the surface 12 and the surface 14, of 0.1 mm or more and 5.0 mm or less, more preferably 0.1 mm or more and 2.0 mm or less, and still more preferably 0.1 mm or more and 0.5 mm or more. A thickness D of 0.1 mm or more can prevent the glass 10 from becoming too thin and can prevent breakage due to the deflection or impact. A thickness D of 2.0 mm or less can prevent the glass from becoming too heavy, and the thickness D of 0.5 mm or less can more suitably prevent the glass from becoming too heavy.

### Characteristics of Glass

Next, characteristics of the glass 10 will be described.

### Young's Modulus

The glass 10 preferably has a Young's modulus E of 110 GPa or more, more preferably 110.5 GPa or more and 125 GPa or less, more preferably 111 GPa or more and 125 GPa or less, more preferably 111 GPa or more and 120 GPa or less, still more preferably 112 GPa or more and 115 GPa or less. The Young's modulus E within this range can appropriately prevent the deflection. A Young's modulus that is too high makes cutting, grinding, and polishing processing difficult.

### Young's Modulus Parameter

The glass 10 preferably has a Young's modulus parameter Y calculated from the composition of 0.8 or more, more preferably 0.85 or more and 1.8 or less, more preferably 0.88 or more and 1.7 or less, more preferably 0.9 or more and 1.6 or less, more preferably 0.93 or more and 1.5 or less, more preferably 0.95 or more and 1.45 or less, more preferably 0.97 or more and 1.4 or less, more preferably 0.98 or more and 1.35 or less, and still more preferably 0.99 or more and 1.3 or less. The Young's modulus within this range can set the Young's modulus E within the above range, and can appropriately prevent the deflection.

The Young's modulus parameter Y is calculated from the following Formula (3).

$$Y = ( 125.36 - 1.42 [ {SiO}_{2} ] - 0.92 [ {Al}_{2} {O}_{3} ] - 1.93 [ {B}_{2} {O}_{3} ] - 0.78 [ MgO ] - 1.13 [ CaO ] - 2.02 [ SrO ] - 1.69 [ BaO ] - 0.48 [ {Li}_{2} O ] - 1.04 [ {K}_{2} O ] - 1. [ ZnO ] - 0.28 [ {ZrO}_{2} ] - 1.41 [ {TiO}_{2} ] + 0.82 [ {Y}_{2} {O}_{3} ] - 0.33 [ {Gd}_{2} {O}_{3} ] - 0.46 [ {La}_{2} {O}_{3} ] ) / 15 \qquad ( 3 )$$

### Density

The glass 10 preferably has a density p of 2.80 g/cm³ or more and 3.80 g/cm³ or less, more preferably 3.00 g/cm³ or more and 3.70 g/cm³ or less, more preferably 3.20 g/cm³ or more and 3.60 g/cm³ or less, more preferably 3.30 g/cm³ or more and 3.50 g/cm³ or less, still more preferably 3.35 g/cm³ or more and 3.45 g/cm³ or less.

### E/ρ

The glass 10 preferably has a ratio of the Young's modulus E to the density ρ (E/ρ) of 32.5 GPa·cm³/g or more and 34.0 GPa·cm³/g or less, more preferably 32.6 GPa·cm³/g or more and 33.5 GPa·cm³/g or less, more preferably 32.7 GPa·cm³/g or more and 33.0 GPa·cm³/g or less, still more preferably 32.8 GPa·cm³/g or more and 32.9 GPa·cm³/g or less. The lower limit of the ratio (E/ρ) within this range can prevent the deflection while preventing the glass from becoming too heavy, thus facilitating handling in the process. The upper limit of the ratio (E/ρ) within this range can prevent the occurrence of cracks during processing.

### Linear Thermal Expansion Coefficient

The glass 10 preferably has a linear thermal expansion coefficient α of 4.5 ppm/° C. or more and 4.7 ppm/° C. or less, more preferably 4.53 ppm/° C. or more and 4.65 ppm/° C. or less, and more preferably 4.55 ppm/° C. or more and 4.60 ppm/° C. or less.

The low linear thermal expansion coefficient as described above can appropriately prevent the deflection. The linear thermal expansion coefficient α is an average thermal expansion coefficient in the range of 50° C. to 200° C., and is a value measured in accordance with DIN-51045-1 as a standard for thermal expansion measurement. For example, the thermal expansion coefficient is measured in a range of 30° C. to 300° C. using a thermal expansion meter DIL 402 Expedis Supreme) manufactured by NETZSCH as a measuring device, and an average thermal expansion coefficient in the range of 50° C. to 200° C. may be defined as the linear thermal expansion coefficient.

### Glass Transition Temperature

The glass 10 preferably has a glass transition temperature Tg of 780° C. or higher and 880° C. or lower, more preferably 790° C. or higher and 870° C. or lower, more preferably 800° C. or higher and 860° C. or lower, more preferably 810° C. or higher and 850° C. or lower, more preferably 815° C. or higher and 840° C. or lower, more preferably 820° C. or higher and 835° C. or lower, and more preferably 825° C. or higher and 830° C. or lower. The glass transition temperature can be measured in accordance with the method defined in JIS R3103-3:2001 “Viscosity and viscometric fixed temperature of glass-Part 3: Determination of dilatometric transformation temperature”.

### Method for Producing Glass

The glass 10 may be produced by any method, and is produced, for example, by the following method. First, a raw material such as silica sand or soda ash, which is a raw material of the compound contained in the glass 10, is heated at a predetermined temperature (for example, 1500° C. to 1600° C.) to be melted. Then, after the melted raw material (glass) is clarified, a molding process of molding the raw material into a plate shape is performed. The molded glass has the composition range of the glass 10 described above on an oxide basis. Then, a slow cooling process is performed on the glass molded in the molding process to produce the glass 10.

Note that the method for producing the glass 10 is not limited to the above, and may be any method. For example, the slow cooling process is not essential. Various methods can be adopted as the molding process in producing the glass 10, and examples thereof include a melt casting method, a down draw method (for example, an overflow down draw method, a slot down method, a redraw method, and the like), a float method, a roll-out method, and a press method.

Next, an example of a production process when the glass 10 is used for FOWLP production will be described. In the FOWLP production, a plurality of semiconductor chips are bonded onto glass 10, and the semiconductor chips are covered with a sealing material to form an element substrate. Then, the glass 10 and the element substrate are separated, and the side of the element substrate opposite to the semiconductor chip is bonded onto, for example, another glass 10. Then, wiring, solder bumps, and the like are formed on the semiconductor chip, and the element substrate and the glass 10 are separated again. Then, the element substrate is cut into pieces for each semiconductor chip to obtain a semiconductor device.

### Effects

As described above, the glass 10 according to the first aspect of the present disclosure has a parameter A of 0.1 or more and 1.0 or less, a parameter B of 1.75 or more and 2.10 or less, and a Young's modulus of 110 GPa or more. In the glass 10 of the present disclosure, since the Young's modulus E is 110 GPa or more, deflection can be appropriately prevented, and since the parameter A is 0.1 or more and 1.0 or less, the coefficient of thermal expansion can be reduced, for example, the linear expansion coefficient α can be set to 4.5 ppm/° C. or more and 4.7 ppm/C or less.

However, glass having a high Young's modulus and a low coefficient of thermal expansion generally tends to have an increased specific elastic modulus E/ρ (Young's modulus/density), and may easily crack during processing. In addition, for example, when the glass has a specific elastic modulus E/ρ that is too small, the glass is easy to fracture and becomes too heavy, so that it may be difficult to handle in the process.

In response to that, as a result of intensive studies, the present inventor has found that the parameter B within the above range can set the specific elastic modulus E/ρ within an appropriate range, such as setting the specific elastic modulus E/ρ to 32.5 GPa·cm³/g or more and 34.0 GPa·cm³/g or less. That is, the glass 10 of the present disclosure having the parameter B in the above range can set the specific elastic modulus E/ρ to an appropriate range to be easily handled in the process and facilitate the production while preventing the occurrence of cracks during processing.

As described above, setting the Young's modulus E and the parameters A and B in the above ranges in the glass 10 of the present disclosure can prevent deflection, can prevent the fracture while reducing the coefficient of thermal expansion, and can facilitate the production.

The glass 10 according to a second aspect of the present disclosure is the glass 10 according to the first aspect, and preferably has a content of RO of more than 0% and 20.0% or less in terms of oxide-based mol %. According to the present disclosure, it is possible to prevent the fracture while reducing the coefficient of thermal expansion and to facilitate the production.

The glass 10 according to a third aspect of the present disclosure is the glass 10 according to the first aspect or the second aspect, and preferably contains 45.0% to 60.0% SiO₂ and 10.0% to 26.0% Al₂O₃ in terms of oxide-based mol %. According to the present disclosure, it is possible to prevent the fracture while reducing the coefficient of thermal expansion and to facilitate the production.

The glass 10 according to a fourth aspect of the present disclosure is the glass 10 according to any one of the first aspect to the third aspect, and preferably contains 0% to 10.0% B₂O₃ in terms of oxide-based mol %. According to the present disclosure, it is possible to prevent the fracture while reducing the coefficient of thermal expansion and to facilitate the production.

The glass 10 according to a fifth aspect of the present disclosure is the glass 10 according to any one of the first aspect to the fourth aspect, and preferably contains 0% to 20.0% MgO in terms of oxide-based mol %. According to the present disclosure, it is possible to prevent the fracture while reducing the coefficient of thermal expansion and to facilitate the production.

The glass 10 according to a sixth aspect of the present disclosure is the glass 10 according to any one of the first aspect to the fifth aspect, and preferably contains 5.0% to 20.0% Y₂O₃ in terms of oxide-based mol %. According to the present disclosure, it is possible to prevent the fracture while reducing the coefficient of thermal expansion and to facilitate the production.

The glass 10 according to a seventh aspect of the present disclosure is the glass 10 according to any one of the first aspect to the sixth aspect, and preferably contains 0% to 20.0% Cao in terms of oxide-based mol %. According to the present disclosure, it is possible to prevent the fracture while reducing the coefficient of thermal expansion and to facilitate the production.

The glass 10 according to an eighth aspect of the present disclosure is the glass 10 according to any one of the first aspect to the seventh aspect, and preferably contains 0% to 20.0% SrO in terms of oxide-based mol %. According to the present disclosure, it is possible to prevent the fracture while reducing the coefficient of thermal expansion and to facilitate the production.

The glass 10 according to a ninth aspect of the present disclosure is the glass 10 according to any one of the first aspect to the eighth aspect, and preferably contains 0% to 20.0% BaO in terms of oxide-based mol %. According to the present disclosure, it is possible to prevent the fracture while reducing the coefficient of thermal expansion and to facilitate the production.

The glass 10 according to a tenth aspect of the present disclosure is the glass 10 according to any one of the first aspect to the ninth aspect, and is preferably used as a substrate. The glass 10 of the present disclosure is suitably used for a substrate.

The glass 10 according to an eleventh aspect of the present disclosure is the glass 10 according to the tenth aspect, and is preferably used for producing at least one of a fan out wafer level package and a fan out panel level package. The glass 10 is suitably used for these applications.

### EXAMPLES

Next, examples will be described. Tables 1 to 3 are tables showing the characteristics of the glass of each example. The embodiment may be changed as long as the effect of the invention is obtained.

TABLE 1

| | Example | Example | Example | Example | Example | Example | Example | Example | Example | Example |
|---|---|---|---|---|---|---|---|---|---|---|
| mol % | 1 | 2 | 3 | 4 | 5 | 6 | 7 | 8 | 9 | 10 |
| SiO₂ | 52.4 | 57.2 | 51.0 | 53.0 | 54.6 | 55.8 | 52.4 | 54.0 | 57.0 | 48.0 |
| Al₂O₃ | 23.4 | 18.9 | 25.0 | 18.0 | 18.9 | 19.2 | 23.3 | 19.0 | 15.0 | 25.0 |
| B₂O₃ | 2.3 | 2.7 | 2.0 | 2.0 | 1.2 | 2.0 | 2.5 | 2.0 | 4.0 | 3.0 |
| MgO | 2.0 | 4.0 | 3.0 | 5.0 | 0.4 | 2.3 | 1.2 | | 5.0 | 4.0 |
| CaO | | 2.0 | 4.0 | 3.0 | 2.2 | | | 2.0 | | 3.0 |
| SrO | 1.7 | 1.0 | | | | | 0.5 | 0.0 | | 0.0 |
| BaO | 4.2 | | 1.0 | 3.0 | 1.0 | 2.5 | 4.1 | 4.0 | | 1.0 |
| Li₂O | | | | | | | | | | |
| Na₂O | | | | | | | | | | |
| K₂O | | | | | | | | | | |
| ZnO | | | | | 5.1 | 0.9 | 0.3 | 5.0 | 1.0 | 2.0 |
| ZrO₂ | 1.0 | 1.2 | 2.0 | | 1.1 | 1.9 | 2.1 | | | |
| TiO₂ | 0.8 | | | 5.0 | 4.3 | 2.6 | 1.0 | 3.0 | 3.0 | 1.0 |
| Y₂O₃ | 11.7 | 10.6 | 8.0 | 8.0 | 8.6 | 11.3 | 11.3 | 10.0 | 12.0 | 9.0 |
| Gd₂O₃ | | | 1.0 | 3.0 | 2.5 | 0.5 | 0.5 | | 2.0 | |
| La₂O₃ | | 2.5 | 3.0 | | | 0.9 | 0.8 | 1.0 | 1.0 | 4.0 |
| P₂O₅ | | | | | | | | | | |
| V₂O₅ | | | | | | | | | | |
| RO | 8.3 | 7.0 | 8.0 | 11.0 | 3.7 | 4.9 | 5.8 | 6.0 | 5.0 | 8.0 |
| RE₂O₃ | 11.7 | 13.1 | 12.0 | 11.0 | 11.1 | 12.7 | 12.7 | 11.0 | 15.0 | 13.0 |
| RO/(SiO₂ + | 0.10 | 0.09 | 0.10 | 0.15 | 0.12 | 0.07 | 0.08 | 0.15 | 0.08 | 0.13 |
| Al₂O₃ + B₂O₃) | | | | | | | | | | |
| MgO/RO | 0.26 | 0.58 | 0.38 | 0.45 | 0.05 | 0.41 | 0.19 | 0.00 | 0.83 | 0.40 |
| (ZrO₂ + | 0.16 | 0.09 | 0.17 | 0.45 | 0.49 | 0.36 | 0.24 | 0.27 | 0.20 | 0.08 |
| TiO₂)/RE₂O₃ | | | | | | | | | | |
| Parameter A | 0.709 | 0.529 | 0.667 | 1.000 | 0.332 | 0.384 | 0.454 | 0.545 | 0.333 | 0.615 |
| Parameter B | 1.946 | 2.054 | 1.937 | 1.782 | 1.797 | 1.965 | 1.895 | 1.782 | 1.984 | 1.930 |
| Parameter Y | 1.39 | 1.43 | 1.45 | 1.05 | 1.22 | 1.47 | 1.48 | 1.12 | 1.49 | 1.49 |
| Tg (° C.) | 800< | 800< | 800< | 800< | 800< | 800< | 800< | 783 | 798 | 778 |
| p (g/cm³) | 3.27 | 3.31 | 3.38 | 3.41 | 3.41 | 3.41 | 3.41 | 3.39 | 3.37 | 3.42 |
| E (GPa) | 110 | 111 | 114 | 112 | 112 | 112 | 112 | 112 | 112 | 111 |
| E/ρ | 33.6 | 33.5 | 33.6 | 32.8 | 32.8 | 32.8 | 32.8 | 33.1 | 33.1 | 32.6 |
| α (ppm/° C., | 4.57 | 4.61 | 4.63 | 4.57 | 4.57 | 4.57 | 4.57 | 4.54 | 4.59 | 4.58 |
| 50-200° C.) | | | | | | | | | | |
| Fracture | ∘ | ∘ | ∘ | ∘ | ∘ | ∘ | ∘ | ∘ | ∘ | ∘ |
| evaluation | | | | | | | | | | |
| Manufac- | ∘ | ∘ | ∘ | ∘ | ∘ | ∘ | ∘ | ∘ | ∘ | ∘ |
| turability | | | | | | | | | | |
| evaluation | | | | | | | | | | |
| Deflection | ⊚ | ⊚ | ⊚ | ⊚ | ⊚ | ⊚ | ⊚ | ⊚ | ⊚ | ⊚ |
| evaluation | | | | | | | | | | |

| | Example | Example | Example | Example | Example | Example | Example |
|---|---|---|---|---|---|---|---|
| mol % | 11 | 12 | 13 | 14 | 15 | 16 | 17 |
| SiO₂ | 50.0 | 51.0 | 51.0 | 49.0 | 48.0 | 48.0 | 53.0 |
| Al₂O₃ | 24.0 | 21.0 | 24.0 | 21.0 | 23.0 | 22.0 | 23.0 |
| B₂O₃ | 2.0 | 1.0 | 2.0 | | 1.0 | 1.0 | 2.0 |
| MgO | | 3.0 | 2.0 | 7.0 | 3.0 | 4.0 | |
| CaO | 2.0 | 5.0 | 3.0 | 4.0 | 5.0 | 2.0 | 2.0 |
| SrO | 1.0 | | 1.0 | | | | 3.0 |
| BaO | 4.0 | | 2.0 | | 1.0 | 2.0 | |
| Li₂O | | | | | | | |
| Na₂O | | | | | | | |
| K₂O | | | | | | | |
| ZnO | | 3.0 | | 3.0 | 4.0 | 4.0 | 1.0 |
| ZrO₂ | | 1.0 | | 1.0 | 3.0 | 3.0 | |
| TiO₂ | 5.0 | 4.0 | 3.0 | 4.0 | 2.0 | 4.0 | 2.0 |
| Y₂O₃ | 10.0 | 8.0 | 9.0 | 9.0 | 8.0 | 9.0 | 12.0 |
| Gd₂O₃ | | 3.0 | 3.0 | 2.0 | | | 1.0 |
| La₂O₃ | 2.0 | | | | 2.0 | 1.0 | 1.0 |
| P₂O₅ | | | | | | | |
| V₂O₅ | | | | | | | |
| RO | 7.0 | 8.0 | 8.0 | 11.0 | 9.0 | 8.0 | 5.0 |
| RE₂O₃ | 12.0 | 11.0 | 12.0 | 11.0 | 10.0 | 10.0 | 14.0 |
| RO/(SiO₂ + | 0.09 | 0.15 | 0.10 | 0.20 | 0.18 | 0.17 | 0.08 |
| Al₂O₃ + B₂O₃) | | | | | | | |
| MgO/RO | 0.00 | 0.27 | 0.25 | 0.50 | 0.23 | 0.33 | 0.00 |
| (ZrO₂ + | 0.42 | 0.45 | 0.25 | 0.45 | 0.50 | 0.70 | 0.14 |
| TiO₂)/RE₂O₃ | | | | | | | |
| Parameter A | 0.583 | 0.727 | 0.667 | 1.000 | 0.900 | 0.800 | 0.357 |
| Parameter B | 1.816 | 1.892 | 1.838 | 2.025 | 1.938 | 1.941 | 1.952 |
| Parameter Y | 1.17 | 1.35 | 1.25 | 1.62 | 1.49 | 1.51 | 1.46 |
| Tg (° C.) | 773 | 795 | 776 | 783 | 780 | 775 | 784 |
| p (g/cm³) | 3.39 | 3.40 | 3.41 | 3.39 | 3.41 | 3.42 | 3.39 |
| E (GPa) | 112 | 112 | 111 | 112 | 113 | 112 | 111 |
| E/ρ | 33.1 | 33.0 | 32.6 | 33.1 | 33.0 | 32.7 | 32.8 |
| α (ppm/° C., | 4.55 | 4.51 | 4.52 | 4.60 | 4.63 | 4.51 | 4.56 |
| 50-200° C.) | | | | | | | |
| Fracture | ∘ | ∘ | ∘ | ∘ | ∘ | ∘ | ∘ |
| evaluation | | | | | | | |
| Manufac- | ∘ | ∘ | ∘ | ∘ | ∘ | ∘ | ∘ |
| turability | | | | | | | |
| evaluation | | | | | | | |
| Deflection | ⊚ | ⊚ | ⊚ | ⊚ | ⊚ | ⊚ | ⊚ |
| evaluation | | | | | | | |

TABLE 2

| | Example | Example | Example | Example | Example | Example | Example | Example | Example | Example |
|---|---|---|---|---|---|---|---|---|---|---|
| mol % | 18 | 19 | 20 | 21 | 22 | 23 | 24 | 25 | 26 | 27 |
| SiO₂ | 54.0 | 51.0 | 56.0 | 51.0 | 51.0 | 50.0 | 53.0 | 52.0 | 52.0 | 53.0 |
| Al₂O₃ | 23.0 | 25.0 | 19.0 | 20.0 | 25.0 | 25.0 | 20.0 | 22.0 | 22.0 | 21.0 |
| B₂O₃ | 2.0 | 2.0 | | 2.0 | 1.0 | 2.0 | 3.0 | 2.0 | | 1.0 |
| MgO | 1.0 | 3.0 | 6.0 | | 5.0 | 0.0 | 3.0 | | 4.0 | 5.0 |
| CaO | 4.0 | 4.0 | | 4.0 | | 3.0 | 2.0 | 5.0 | 3.0 | 4.0 |
| SrO | | | | | | | | | | |
| BaO | | 1.0 | 2.0 | 2.0 | 5.0 | 5.0 | 0.0 | 1.0 | 1.0 | |
| Li₂O | | | | | | | | | | |
| Na₂O | | | | | | | | | | |
| K₂O | | | | | | | | | | |
| ZnO | 1.0 | | 1.0 | 2.0 | 1.0 | 1.0 | | | 1.0 | |
| ZrO₂ | | 2.0 | 3.0 | 3.0 | | 2.0 | 3.0 | 3.0 | 3.0 | 3.0 |
| TiO₂ | 1.0 | | 2.0 | 5.0 | | 2.0 | 2.0 | 4.0 | 3.0 | 2.0 |
| Y₂O₃ | 9.0 | 8.0 | 8.0 | 10.0 | 12.0 | 9.0 | 12.0 | 7.0 | 8.0 | 8.0 |
| Gd₂O₃ | 2.0 | 1.0 | | | | | | 2.0 | 1.0 | 3.0 |
| La₂O₃ | 3.0 | 3.0 | 3.0 | 1.0 | | 1.0 | 2.0 | 2.0 | 2.0 | |
| P₂O₅ | | | | | | | | | | |
| V₂O₅ | | | | | | | | | | |
| RO | 5.0 | 8.0 | 8.0 | 6.0 | 10.0 | 8.0 | 5.0 | 6.0 | 8.0 | 9.0 |
| RE₂O₃ | 14.0 | 12.0 | 11.0 | 11.0 | 12.0 | 10.0 | 14.0 | 11.0 | 11.0 | 11.0 |
| RO/(SiO₂ + | 0.08 | 0.10 | 0.12 | 0.11 | 0.14 | 0.12 | 0.07 | 0.08 | 0.12 | 0.12 |
| Al₂O₃ + B₂O₃) | | | | | | | | | | |
| MgO/RO | 0.17 | 0.38 | 0.67 | 0.00 | 0.45 | 0.00 | 0.60 | 0.00 | 0.44 | 0.56 |
| (ZrO₂ + | 0.07 | 0.17 | 0.45 | 0.73 | 0.00 | 0.40 | 0.36 | 0.64 | 0.55 | 0.45 |
| TiO₂)/RE₂O₃ | | | | | | | | | | |
| Parameter A | 0.357 | 0.667 | 0.727 | 0.545 | 0.833 | 0.800 | 0.357 | 0.545 | 0.727 | 0.818 |
| Parameter B | 1.889 | 1.937 | 1.932 | 1.925 | 2.026 | 1.836 | 2.096 | 1.810 | 1.950 | 1.984 |
| Parameter Y | 1.42 | 1.45 | 1.38 | 1.37 | 1.63 | 1.21 | 1.77 | 1.18 | 1.49 | 1.49 |
| Tg (° C.) | 801 | 787 | 789 | 784 | 781 | 787 | 804 | 791 | 786 | 806 |
| p (g/cm³) | 3.43 | 3.40 | 3.37 | 3.37 | 3.39 | 3.38 | 3.38 | 3.40 | 3.40 | 3.37 |
| E (GPa) | 113 | 112 | 111 | 112 | 112 | 112 | 114 | 111 | 112 | 113 |
| E/ρ | 32.9 | 32.8 | 33.0 | 33.2 | 33.0 | 33.2 | 33.7 | 32.7 | 32.8 | 33.5 |
| α (ppm/° C., | 4.52 | 4.56 | 4.56 | 4.58 | 4.55 | 4.52 | 4.59 | 4.53 | 4.55 | 4.55 |
| 50-200° C.) | | | | | | | | | | |
| Fracture | ∘ | ∘ | ∘ | ∘ | ∘ | ∘ | ∘ | ∘ | ∘ | ∘ |
| evaluation | | | | | | | | | | |
| Manufac- | ∘ | ∘ | ∘ | ∘ | ∘ | ∘ | ∘ | ∘ | ∘ | ∘ |
| turability | | | | | | | | | | |
| evaluation | | | | | | | | | | |
| Deflection | ⊚ | ⊚ | ⊚ | ⊚ | ⊚ | ⊚ | ⊚ | ⊚ | ⊚ | ⊚ |
| evaluation | | | | | | | | | | |

| | Example | Example | Example | Example | Example | Example | Example |
|---|---|---|---|---|---|---|---|
| mol % | 28 | 29 | 30 | 31 | 32 | 33 | 34 |
| SiO₂ | 48.4 | 51.5 | 50.5 | 50.0 | 45.7 | 55.0 | 50.0 |
| Al₂O₃ | 17.9 | 15.6 | 15.3 | 16.3 | 19.8 | 22.7 | 20.0 |
| B₂O₃ | 6.0 | 2.3 | 0.9 | 1.4 | 2.5 | | |
| MgO | 8.3 | 9.8 | 9.6 | 6.9 | 8.0 | | |
| CaO | 7.4 | 9.9 | 9.7 | 14.1 | 10.0 | | |
| SrO | | | | 0.6 | 0.8 | | |
| BaO | | | | | 0.5 | | |
| Li₂O | | | | | | | |
| Na₂O | | | | | | | |
| K₂O | | | | | | | |
| ZnO | 1.0 | | | | | | |
| ZrO₂ | | | | | | | |
| TiO₂ | 1.0 | 2.0 | 6.3 | 3.0 | 5.7 | | 10.0 |
| Y₂O₃ | 9.2 | 8.4 | 6.9 | 7.7 | 6.5 | 22.3 | 10.0 |
| Gd₂O₃ | | | | | | | |
| La₂O₃ | | | | | | | 10.0 |
| P₂O₅ | | | | | | | |
| V₂O₅ | | | | | | | |
| RO | 15.7 | 19.8 | 19.7 | 21.6 | 19.3 | 0.0 | 0.0 |
| RE₂O₃ | 9.5 | 8.4 | 6.9 | 7.7 | 6.8 | 22.3 | 20.0 |
| RO/(SiO₂ + | 0.23 | 0.28 | 0.29 | 0.32 | 0.28 | 0.00 | 0.00 |
| Al₂O₃ + B₂O₃) | | | | | | | |
| MgO/RO | 0.49 | 0.50 | 0.50 | 0.32 | 0.41 | | |
| (ZrO₂ + | 0.11 | 0.24 | 0.92 | 0.39 | 0.85 | 0.00 | 0.50 |
| TiO₂)/RE₂O₃ | | | | | | | |
| Parameter A | 1.656 | 2.341 | 2.861 | 2.800 | 2.851 | 0.000 | 0.000 |
| Parameter B | 2.147 | 2.207 | 2.147 | 2.141 | 2.083 | 2.341 | 1.650 |
| Parameter Y | 1.25 | 1.24 | 1.07 | 1.09 | 0.97 | 2.97 | 1.70 |
| Tg (° C.) | 762 | 780 | 780 | 790 | 771 | 801 | 794 |
| p (g/cm³) | 3.10 | 3.05 | 3.02 | 3.08 | 3.09 | 3.57 | 3.79 |
| E (GPa) | 106 | 108 | 110 | 112 | 111 | 115 | 115 |
| E/ρ | 34.1 | 35.5 | 36.5 | 36.5 | 35.8 | 32.1 | 30.3 |
| α (ppm/° C., | 4.72 | 4.95 | 4.79 | 5.19 | 4.73 | 4.87 | 5.15 |
| 50-200° C.) | | | | | | | |
| Fracture | x | x | x | x | x | ∘ | ∘ |
| evaluation | | | | | | | |
| Manufac- | ∘ | ∘ | ∘ | ∘ | ∘ | x | x |
| turability | | | | | | | |
| evaluation | | | | | | | |
| Deflection | ∘ | x | x | x | ∘ | x | x |
| evaluation | | | | | | | |

| | Example | Example | Example | Example | Example | Example | Example | Example | Example | Example |
|---|---|---|---|---|---|---|---|---|---|---|
| mol % | 35 | 36 | 37 | 38 | 39 | 40 | 41 | 42 | 43 | 44 |
| SiO₂ | 52.5 | 60.0 | 60.0 | 60.0 | 60.0 | 54.7 | 45.0 | 55.4 | 50.0 | 45.0 |
| Al₂O₃ | 14.2 | 10.0 | 10.0 | 10.0 | 10.0 | 22.6 | 17.5 | 19.4 | 10.0 | 17.5 |
| B₂O₃ | 4.8 | | | | | | | | | |
| MgO | 1.5 | 20.0 | | 10.0 | | | | | | 17.5 |
| CaO | | | | | 20.0 | | | | 15.0 | |
| SrO | | | | | | | | | | |
| BaO | 18.5 | | 20.0 | 10.0 | | | | | 15.0 | |
| Li₂O | | | | | | | | | | 5.0 |
| Na₂O | | | | | | | | | | |
| K₂O | | | | | | | | | | |
| ZnO | | | | | | | 20.0 | | | |
| ZrO₂ | | | | | | | | 5.9 | | |
| TiO₂ | | | | | | | | | | 5.0 |
| Y₂O₃ | 6.2 | 10.0 | 10.0 | 10.0 | 10.0 | 11.1 | 17.5 | 19.3 | 10.0 | 10.0 |
| Gd₂O₃ | | | | | | | | | | |
| La₂O₃ | | | | | | 11.1 | | | | |
| P₂O₅ | 2.3 | | | | | | | | | |
| V₂O₅ | | | | | | 0.5 | | | | |
| RO | 20.0 | 20.0 | 20.0 | 20.0 | 20.0 | 0.0 | 0.0 | 0.0 | 30.0 | 17.5 |
| RE₂O₃ | 6.2 | 10.0 | 10.0 | 10.0 | 10.0 | 22.2 | 17.5 | 19.3 | 10.0 | 10.0 |
| RO/(SiO₂ + | 0.28 | 0.29 | 0.29 | 0.29 | 0.29 | 0.00 | 0.32 | 0.00 | 0.50 | 0.28 |
| Al₂O₃ + B₂O₃) | | | | | | | | | | |
| MgO/RO | 0.08 | 1.00 | 0.00 | 0.50 | 0.00 | | 0.00 | | 0.00 | 1.00 |
| (ZrO₂ + | 0.00 | 0.00 | 0.00 | 0.00 | 0.00 | 0.00 | 0.00 | 0.31 | 0.00 | 0.50 |
| TiO₂)/RE₂O₃ | | | | | | | | | | |
| Parameter A | 3.226 | 2.000 | 2.000 | 2.000 | 2.000 | 0.000 | 0.000 | 0.000 | 3.000 | 1.750 |
| Parameter B | 0.930 | 2.354 | 0.861 | 1.702 | 2.122 | 1.723 | 1.867 | 2.253 | 1.229 | 2.372 |
| Parameter Y | 0.03 | 1.56 | 0.35 | 0.95 | 1.10 | 2.06 | 2.64 | 2.87 | 0.73 | 2.02 |
| Tg (° C.) | 764 | 815 | 880 | 840 | 804 | 801 | 784 | 809 | 781 | 711 |
| p (g/cm³) | 3.45 | 3.16 | 3.76 | 3.41 | 3.14 | 3.88 | 3.85 | 3.66 | 3.40 | 3.21 |
| E (GPa) | 106 | 114 | 111 | 112 | 114 | 113 | 110 | 112 | 110 | 126 |
| E/ρ | 30.6 | 35.9 | 29.6 | 33.0 | 36.2 | 29.2 | 28.6 | 30.6 | 32.3 | 39.3 |
| α (ppm/° C., | 5.96 | 4.77 | 6.65 | 5.71 | 5.75 | 5.43 | 5.24 | 5.07 | 7.58 | 5.39 |
| 50-200° C.) | | | | | | | | | | |
| Fracture | ∘ | x | ∘ | ∘ | x | ∘ | ∘ | ∘ | ∘ | x |
| evaluation | | | | | | | | | | |
| Manufac- | x | ∘ | x | ∘ | ∘ | x | x | x | x | ∘ |
| turability | | | | | | | | | | |
| evaluation | | | | | | | | | | |
| Deflection | x | ∘ | x | x | x | x | x | x | x | x |
| evaluation | | | | | | | | | | |

| | Example | Example | Example | Example | Example | Example | Example |
|---|---|---|---|---|---|---|---|
| mol % | 45 | 46 | 47 | 48 | 49 | 50 | 51 |
| SiO₂ | 45.0 | 53.0 | 45.9 | 56.8 | 59.0 | 57.1 | 59.1 |
| Al₂O₃ | 23.0 | 14.0 | 23.6 | 16.7 | 20.5 | 16.9 | 22.4 |
| B₂O₃ | | | | | | 8.7 | |
| MgO | 20.0 | 7.0 | | | | | |
| CaO | | 7.0 | | 15.2 | | | 5.0 |
| SrO | | | | | | | |
| BaO | | | | | | | |
| Li₂O | | 6.0 | 15.8 | | | | |
| Na₂O | | | | | 14.0 | 0.8 | |
| K₂O | | | | | 0.0 | 2.2 | |
| ZnO | | 3.0 | | | | | |
| ZrO₂ | | 2.0 | | | | | |
| TiO₂ | 7.0 | 3.0 | | | | | |
| Y₂O₃ | 5.0 | 5.0 | 14.2 | 11.3 | 6.5 | 5.7 | 13.5 |
| Gd₂O₃ | | | | | | | |
| La₂O₃ | | | | | | 8.6 | |
| P₂O₅ | | | | | | | |
| V₂O₅ | | | | | | | |
| RO | 20.0 | 14.0 | 0.0 | 15.2 | 0.0 | 0.0 | 5.0 |
| RE₂O₃ | 5.0 | 5.0 | 14.2 | 11.3 | 6.5 | 14.4 | 13.5 |
| RO/(SiO₂ + | 0.29 | 0.25 | 0.00 | 0.21 | 0.00 | 0.00 | 0.06 |
| Al₂O₃ + B₂O₃) | | | | | | | |
| MgO/RO | 1.00 | 0.41 | | 0.00 | | | 0.00 |
| (ZrO₂ + | 1.40 | 1.00 | 0.00 | 0.00 | 0.00 | 0.00 | 0.00 |
| TiO₂)/RE₂O₃ | | | | | | | |
| Parameter A | 4.000 | 2.800 | 0.000 | 1.342 | 0.000 | 0.000 | 0.371 |
| Parameter B | 2.321 | 2.150 | 2.441 | 2.189 | 2.342 | 1.590 | 2.273 |
| Parameter Y | 1.25 | 1.15 | 2.83 | 1.43 | 1.20 | 0.65 | 1.74 |
| Tg (° C.) | 768 | 780 | 785 | 807 | 793 | 771 | 806 |
| p (g/cm³) | 2.96 | 3.00 | 3.44 | 3.15 | 2.77 | 3.36 | 3.20 |
| E (GPa) | 122 | 111 | 112 | 114 | 107 | 102 | 114 |
| E/ρ | 41.2 | 37.0 | 32.5 | 36.2 | 38.5 | 30.3 | 35.6 |
| α (ppm/° C., | 3.80 | 5.36 | 6.69 | 5.22 | 4.86 | 5.23 | 4.20 |
| 50-200° C.) | | | | | | | |
| Fracture | x | x | ∘ | x | x | ∘ | x |
| evaluation | | | | | | | |
| Manufac- | ∘ | ∘ | x | ∘ | ∘ | x | ∘ |
| turability | | | | | | | |
| evaluation | | | | | | | |
| Deflection | x | x | x | x | x | x | x |
| evaluation | | | | | | | |

### Example 1

In Example 1, glass having the composition shown in Table 1 was manufactured. In Example 1, a raw plate having a diameter of 320 mm and a thickness of 6 mm was produced using a melt casting method. Next, a plurality of plates having a diameter of 300 mm and a thickness of 3 mm were cut out from the center of the raw plate. Both surfaces of these plates were polished using cerium oxide as a polishing material to obtain glass having a thickness of 0.7 mm.

For the glass of Example 1, the parameter A was calculated using the above-described Formula (1).

For the glass of Example 1, the parameter B was calculated using the above-described Formula (2).

For the glass of Example 1, the Young's modulus parameter Y was calculated using the above-described Formula (3).

The glass transition temperature Tg (° C.) of the glass of Example 1 was measured. The glass transition temperature was measured in accordance with the method defined in JIS R3103-3:2001 “Viscosity and viscometric fixed temperature of glass-Part 3: Determination of dilatometric transformation temperature”.

For the glass of Example 1, the density ρ (g/cm³) was measured. The density was measured by the Archimedes's method.

For the glass of Example 1, the Young's modulus E (GPa) was measured. The Young's modulus was measured by an ultrasonic pulse method defined in JIS R 1602:1995 “Testing methods for elastic modulus of fine ceramics”. The bulk density of the sample was measured by the Archimedes's method, the longitudinal wave velocity and the transverse wave velocity were measured using an ultrasonic thickness meter 38DL PLUS manufactured by OLYMPUS, and the value of Young's modulus was determined. In addition, the ratio of the Young's modulus E to the density ρ (E/ρ) was calculated.

The linear thermal expansion coefficient α (ppm/° C.) of the glass of Example 1 was measured. The thermal expansion coefficient was measured in a range of 30° C. to 300° C. using a thermal expansion meter (DIL 402 Expedis Supreme) manufactured by NETZSCH as a measuring device, and an average thermal expansion coefficient in the range of 50° C. to 200° C. was defined as the linear thermal expansion coefficient α.

The results of each measurement and calculation are shown in Table 1.

### Examples 2 to 51

In Examples 2 to 51, glass was produced in the same manner as in Example 1 except that the composition of the glass was as shown in Tables 1 to 3. The results of the measurement and the calculation of each example are shown in Tables 1 to 3.

### Evaluation

For the glass of each example, manufacturability evaluation, fracture evaluation, and deflection evaluation were performed.

In the fracture evaluation, a case where the ratio of the Young's modulus E to the density ρ (E/ρ) of the glass 10 was 34.0 GPa·cm³/g or less was evaluated as ∘, and a case where the ratio was 34.0 GPa·cm³/g or more was evaluated as X.

In the manufacturability evaluation, a case where the ratio of the Young's modulus E to the density ρ (E/ρ) of the glass 10 was 32.5 GPa·cm³/g or more was evaluated as ∘, and a case where the ratio was 32.5 GPa·cm³/g or less was evaluated as X.

The deflection evaluation was carried out on the basis of the Bi-Metal warpage calculation defined in the document S. Timoshenko, “Analysis of Bi-Metal Thermostats” J. Opt. Soc. Am. 11 (1925) 233. FIG. 2 is a schematic view for explaining deflection evaluation. Here, as illustrated in FIG. 2, the amount of warpage δ is defined as a displacement amount in either the vertical upward or downward direction of the end portions of the glass 10 with the center of the second surface 14 as a height reference when the semiconductor substrate is cooled from a high temperature state of 200° C. to a low temperature of 20° C. in a process of molding and bonding the semiconductor substrate with a resin to the first surface 12 of the glass 10 processed into the shape of FIG. 1. Specifically, the amount of warpage δ is calculated by the following Formula (5).

$$δ = \frac{6 {L}^{2} ( {α}_{2} - {α}_{1} ) ( θ2 - θ1 ) {( 1 + m )}^{2}}{8 h [ 3 {( 1 + m )}^{2} + ( 1 + mn ) \{ {m}^{2} + {( mn )}^{- 1} \} ]} \qquad ( 5 )$$

Here, as illustrated in FIG. 2, L is a length of the glass 10 in a warpage direction (a lateral direction in FIG. 2), α₁ is a linear thermal expansion coefficient of the resin substrate 20, α₂ is a linear thermal expansion coefficient of the glass 10, Θ₁ is a temperature after cooling (here, 20° C.), and Θ₂ is a temperature before cooling (here, 200° C.). In addition, m is a₁/a₂, h is a₁+a₂, and n is E₁/E₂. Here, a₁ is a thickness of the resin substrate 20, a₂ is a thickness of the glass 10, E₁ is a Young's modulus of the resin substrate 20, and E₂ is a Young's modulus of the glass 10. In the deflection evaluation, the thickness of the resin substrate 20 to be bonded to the glass 10 was assumed to be 0.3 mm and the Young's modulus of the resin substrate 20 was assumed to be 31.5 GPa in consideration of mounting a semiconductor. In consideration of applying to various production processes, the linear thermal expansion coefficient α₁ of the resin substrate 20 is assumed for the following three patterns: 4.5 ppm/° C., 4.6 ppm/° C., and 4.7 ppm/° C., and the amounts of warpage 81, 82, and 83 of the glass 10 having a thickness 0.7 mm and a length L of 300 mm are calculated. In the determination of the deflection, a case where the average value δ of the absolute values |δ₁|, |δ₂|, and |δ₃| of the respective calculated values was 0.19 mm or less was evaluated as ⊚, a case where the average value δ was 0.30 mm or less was evaluated as ∘, and a case where the average value δ was higher than 0.30 mm was evaluated as X. It can be confirmed that the deflection can be prevented and the coefficient of thermal expansion can be lowered by being ∘ and ⊚ in the determination of the deflection.

As shown in Tables 1 to 3, the glass of Examples 1 to 27 having a parameter A of 0.1 or more and 1.0 or less, a parameter B of 1.75 or more and 2.10 or less, and a Young's modulus of 110 GPa or more were evaluated as ∘ or ⊚ (pass) in all of the fracture evaluation, the manufacturability evaluation, and the deflection evaluation, can prevent the fracture while reducing the coefficient of thermal expansion, and can facilitate the production.

Meanwhile, the glass of Example 28 to 51 (Comparative Example) that does not satisfy at least one of the condition that the parameter A is 0.1 or more and 1.0 or less, the condition that the parameter B is 1.75 or more and 2.10 or less, and the Young's modulus is 110 GPa or more was evaluated as X (failed) in at least one of the thermal expansion evaluation, the manufacturability evaluation, the fracture evaluation, and the deflection evaluation, and it can be seen that the glass cannot prevent the fracture while reducing the coefficient of thermal expansion, and cannot facilitate the production.

According to the present invention, it is possible to prevent fracture while reducing the coefficient of thermal expansion and to facilitate the production.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. Glass having a parameter A represented by Formula (1) of 0.1 or more and 1.0 or less,
a parameter B represented by Formula (2) of 1.75 or more and 2.10 or less, and
a Young's modulus of 110 GPa or more:
$$A = [ R O ] / [ {RE}_{2} {O}_{3} ] \qquad ( 1 )$$
$$B = {\{ ( 441 - 2.845 \times [ {SiO}_{2} ] - 1.833 \times [ {Al}_{2} {O}_{3} ] - 3.864 \times [ {B}_{2} {O}_{3} ] - 1.569 \times [ MgO ] - 2.252 \times [ CaO ] - 4.031 \times [ SrO ] - 3.384 \times [ BaO ] - 0.956 \times [ {Li}_{2} O ] - 2. \times [ ZnO ] - 0.554 \times [ {ZrO}_{2} ] - 2.815 \times [ {TiO}_{2} ] + 1.636 \times [ {Y}_{2} {O}_{3} ] - 0.651 \times [ {Gd}_{2} {O}_{3} ] - 0.911 \times [ {La}_{2} {O}_{3} ] ) / ( 29.637 - 0.1851 \times [ {SiO}_{2} ] - 0.1408 \times [ {Al}_{2} {O}_{3} ] - 0.1984 \times [ {B}_{2} {O}_{3} ] - 0.1343 \times [ MgO ] - 0.1271 \times [ CaO ] - 0.0556 \times [ SrO ] + 0.0369 \times [ BaO ] - 0.1083 \times [ {Li}_{2} O ] - 0.0134 \times [ ZnO ] + 0.0192 \times [ {ZrO}_{2} ] - 0.1408 \times [ {TiO}_{2} ] + 0.0794 \times [ {Y}_{2} {O}_{3} ] + 0.3092 \times [ {Gd}_{2} {O}_{3} ] + 0.1983 \times [ {La}_{2} {O}_{3} ] ) - 10 \}}^{0.5} \qquad ( 2 )$$
wherein RO is an oxide of a divalent metal R, and RE₂O₃ is an oxide of a trivalent rare earth metal RE.

2. The glass according to claim 1, having a content of RO of more than 0% and 20.0% or less in terms of oxide-based mol %.

3. The glass according to claim 1 comprising:
45.0% to 60.0% SiO₂, and
10.0% to 26.0% Al₂O₃
in terms of oxide-based mol %.

4. The glass according to claim 1, comprising:
0% to 10.0% B₂O₃
in terms of oxide-based mol %.

5. The glass according to claim 1, comprising:
0% to 20.0% MgO
in terms of oxide-based mol %.

6. The glass according to claim 1, comprising:
5.0% to 20.0% Y₂O₃
in terms of oxide-based mol %.

7. The glass according to claim 1, comprising:
0% to 20.0% CaO
in terms of oxide-based mol %.

8. The glass according to claim 1, comprising:
0% to 20.0% SrO
in terms of oxide-based mol %.

9. The glass according to claim 1, comprising:
0% to 20.0% BaO
in terms of oxide-based mol %.

10. The glass according to claim 1, comprising:
10.0% to 20.0% RE₂O₃, and
7.0% to 12.0% Y₂O₃
in terms of oxide-based mol %.

11. The glass according to claim 1, wherein the glass does not substantially contain an alkali metal oxide.

12. The glass according to claim 1 or 2, having a ratio of a content of RO to a total content of SiO₂, Al₂O₃, and B₂O₃ ((RO)/(SiO₂+Al₂O₃+B₂O₃)) of 0.00 or more and 0.50 or less.

13. The glass according to claim 1, having a ratio of a content of MgO to a content of RO ((MgO)/(RO)) of 0.10 or more and 0.90 or less.

14. The glass according to claim 1, having a ratio of a total content of ZrO₂+TiO₂ to a content of RE₂O₃ ((ZrO₂+TiO₂)/(RE₂O₃)) of 0.05 or more and 0.90 or less in terms of oxide-based mol %.

15. The glass according to claim 1, having a Young's modulus parameter Y calculated from composition of 0.8 or more.

16. The glass according to claim 1, having a Young's modulus E of 111 GPa or more and 125 GPa or less.

17. The glass according to claim 1, having a ratio of Young's modulus E to density ρ (E/ρ) of 32.5 GPa·cm³/g or more and 34.0 GPa·cm³/g or less.

18. The glass according to claim 1, having a linear thermal expansion coefficient α of 4.5 ppm/° C. or more and 4.7 ppm/° C. or less.

19. The glass according to claim 1, used as a substrate.

20. The glass according to claim 19, for use in production of at least one of a fan out wafer level package and a fan out panel level package.
